(19) United States
(12) Patent Application Publication
(10) Pub. No.: US 2011/0163051 A1
(43) Pub. Date: Jul. 7, 2011

(54) SUPPORT STRUCTURE OF PHOTOVOLTAIC DEVICE

(76) Inventor: Petr Horanek, Plzen (CZ)

(21) Appl. No.: 13/062,155

(22) PCT Filed: Sep. 9, 2009
(86) PCT No.: PCT/CZ2009/000109

§ 371 Date: Mar. 3, 2011

(30) Foreign Application Priority Data
Sep. 10, 2008 (CZ) PV 2008-550
Feb. 27, 2009 (CZ) PUV 2009-20922
Jul. 31, 2009 (CZ) PUV 2009-21532

(51) Int. Cl. H01L 23/32

(52) U.S. Cl. 211/26

(57) ABSTRACT

Support structure of photovoltaic devices is adapted for anchoring on drilling bases (8) at unreinforced surfaces or on holders (12) at reinforced surfaces. The structure may include a rear leg (5), a front leg (9), a rear beam (4), a bottom beam (6), and a supporting beam (1). The internal angles in the triangle formed by the supporting beam (1), bottom beam (6) and the rear beam (4), equal 60° with the tolerance of ±5°. The distance between the top part of the rear beam (4) and the central axis (O) is less than the distance between the bottom part of the rear beam (4) and the central axis (O). The bottom beam (6) is situated so that the connection of the front leg (9) with the bottom beam (6) is located higher than the connection of the bottom beam (6) with the rear leg (5). Alternatively, the rear beam (4) is situated vertically and the values of each internal angle in the triangle formed by the supporting beam (1), bottom beam (6), and the rear beam (4), are in the extent of 45° to 75°. The connection of the bottom beam (6) to the front leg (9) and/or the supporting beam (1) lies higher than the connection of the bottom beam (6) to the rear leg (5) and/or the rear beam (4). The triangle consisting of the bottom beam (6), supporting beam (1) and the rear beam (4) can also be formed so that the rear beam (4) is directed vertically and its connection to the bottom beam (6) is made at the angle of 90°±15°.

### TECHNICAL FIELD

The invention relates to the support structure of solar or photovoltaic panels and belongs to the area of assembling or supporting solar or photovoltaic panels, respectively.

### BACKGROUND ART

Support structures for photovoltaic panels are known in many variants and realizations. As a rule, the rigid structures have two legs which are interconnected mutually with one bottom beam at least and contain mostly one rear beam and a supporting beam at least. To the supporting beam, longitudinal struts can be joined interconnecting mutually individual structures with the photovoltaic panels being located on these longitudinal struts. As a rule, the structures are designed as for static properties only without expressive effort to unload the structure and to save the used material.

The structures are widely used which are screwed together of individual tubes or beams at the site of installation. These individual tubes and/or beams are interconnected by means of screw joints and clamps. However, this solution is comparatively expensive with regard to properties of used building elements and moreover need not provide satisfying stability necessarily, e.g. if larger photovoltaic panels are used.

A rigid support structure, enjoining the industrial protection, is the one described in the document DE20311967U. Here, a metallic support structure is described with trapezoidal side elevation. The photovoltaic panels are fixed by means of screws to the top part of the structure which lies on distance elements as well. Below these distance elements, a plastic base plate is located which is shaped to have flat areas separated with projecting semicircular parts. At these semicircular parts the distance elements are fastened. The plastic basic plates can be placed possibly below the earth surface and their rims can overlap mutually. The disadvantage of this solution consists partly in the shape of the actual metallic support structure, requesting relatively strong material, partly in application of plastic fundamental plates which must be installed by more extensive earthworks. The positioning structures, utilized because of different inclinations of photovoltaic panels in the months of summer and winter, are solved in many ways at present. One of them is described e.g. in the document DE20319065U. The structure, presented here for several photovoltaic panels, has so many legs as many photovoltaic panels are installed at the structure. The legs are joined horizontally with a horizontally placed rotating shaft. Perpendicularly to this rotating shaft, several cross bars are installed between which the photovoltaic panels are inserted. Then, the rotating cross bar passes under the photovoltaic panels at the centre of their length approximately. The disadvantage of this solution consists in a great number of legs buried into the earth with one leg corresponding to one installed photovoltaic panel.

Further possible solution of the positioning location of photovoltaic panels consists in devices adjustable in two axes (horizontal and vertical one), the so called trackers. However, they are solved in quite other ways substantially than the proposed support structure whence they are not described in this document therefore.

The proposed technical solution presents a stable support structure with highest possible unloading. Primarily, the structure is designed to be stable but can be made as positioning one with small adjustments during production thereof. All this has positive influence on the final price of the product. The structure can be utilized for installations at free or roof surfaces.

### DISCLOSURE OF INVENTION

The main substance of the technical solution is to utilize the slightest possible (and cheapest therefore) structure components with keeping ideal distribution of angles and dimensions in the structure as well which enables to maintain necessary loading capacity along with stability. The support structure always consists of a basic triangle composed of a supporting beam, a rear beam and a bottom beam, with this triangle being located on a front leg and a rear leg.

In the first solution, the internal angles of the triangle are approximately equal, said triangle being composed of the supporting beam, the bottom beam and the rear beam. Therefore, each of these angles equals 60° with the tolerance of ±5°. In the side view of the structure, this triangle is situated so that the top part of the rear beam is located closer to the central axis in question than the bottom part of the rear beam. Simultaneously, the bottom beam is situated so that the joint of the front leg to the bottom beam lies higher than the joint of the rear leg to the bottom beam.

An alternative solution consists in the different shape of the structure triangle composed of the supporting beam, the bottom one, and the rear one, and in different location of said triangle in the structure. Here, the triangle is made so that the rear beam is situated vertically and the size of each internal angle in the triangle, consisting of the supporting beam, the rear beam, and the bottom beam, is in the extent of 45° to 75°. Simultaneously, the joint between the bottom beam and the front leg and/or the supporting beam lies higher than the joint of the bottom beam with the rear leg and/or the rear beam.

Another solution differs from the preceding ones in the form of the structure triangle again. In this variant, the triangle consists of the supporting beam, rear one, and the bottom one so that the rear beam is directed vertically and its joint with the bottom beam is made at the angle of 90°±15°.

The support structure, suitable for high load with photovoltaic panels, is defined so that the supporting beam is 4000 mm long at least along with the spacing between the front leg and the rear leg being greater than 1400 mm.

In the supporting beam, there are orifices to install clips for attachment of longitudinal struts which interconnect individual structures mutually which are distant several meters one to the other. On these longitudinal struts the actual photovoltaic panels are mounted.

In an alternate solution, a U-section beam is chosen as supporting with dimensions of approximately 60 mm×40 mm which has sufficient loading capacity in its whole length to support the photovoltaic panel weight. Then, at the joining point with the bottom beam and on that with the rear beam, the supporting beam is always underlaid with one strut in order to distribute the spot pressure over greater length of the supporting beam.

The structures, according to proposed technical solution, are utilized in combination with drilling bases (PV 2008-522) advantageously. In case the drilling bases are located inaccurately in the earth (in the stony earth especially) and the distance between their ends would not correspond to the spacing of the structure legs, the alternate solution of the base can be utilized in which at least one leg can be shifted over the bottom beam at least. Due to it, the spacing of the legs can be set according to diversely distant drilling bases or possibly other columns and clips respectively.

Further alternative solution of the structure consists in a position-setting one the position of which can be adjusted so that the longitudinal axis of the supporting beam can be set continuously from 30° to 50° approximately compared to the horizontal line in compliance with customer's demands. The positioning structure differs from the above described solutions as for the attachment of the front and rear legs to the rest part of the structure. The rear leg is joined by means of a pivot to the rest of the structure. The longitudinal axis of rotation of the pivot is situated horizontally and perpendicularly to the bottom beam. The front leg is attached to the bottom beam in a sliding way. The sliding joint can be made with usual screwing clamp or with a positioning plate and a glider with a clamping plate. In such case the positioning plate is firmly connected to the bottom beam, no matter from top or bottom side. The positioning plate is provided with at least two pairs of orifices so that these are at those two sides of the positioning plate which are parallel to the bottom beam. At the top end, the front leg is provided with the glider with the clamping plate. The glider has hemispheric shape on the side cross section. Under the glider, the clamping plate is located in which there are two orifices, one at each lateral side. In both orifices in the clamping plate there are screws, with these two screws passing always through one pair of orifices in the positioning plate. During the production of the positioning plate, the position of each pair of orifices therein is chosen with respect to predefined requested inclinations of the supporting beam (and of the photovoltaic panel, too) in the course of the year. In case the inclination of the photovoltaic panel should be changed, the screws are taken out from the given pair of orifices in the positioning plate and after the inclination having been set, they are inserted into another pair of orifices in the positioning plate. The more orifice pairs are in the positioning plate the more positions of the support structure can be set. This solution enables simple and useful inclination change because any newly set inclination need not be measured thanks to the predefined pairs of orifices in the positioning plate as the possible inclination angles have been given yet by individual pairs of orifices in the positioning plate.

In the same way, the solution can be utilized in which the front leg is attached to the rest part of the structure by means of the pivot and the rear leg is attached to the rest part of the structure in a sliding way by means of a screwing clamp or of the positioning plate and the glider with the clamping plate. With greater loads with photoelectric panels expected or weaker beams used, the support structure has to be suitably reinforced with one strut at least. The strut can be located inside the triangle consisting of the supporting beam, the rear beam and the bottom beam. In some cases the strut can be placed between the rear beam or the supporting beam respectively or the front leg and/or rear one.

Advantageously, the supporting beam can be composed of two L-section beams. These L-section beams are located upwards with their horizontal parts and with their vertical parts mutually to one another. Between these vertical parts there is an assembling gap for installing the screws which hold the assembling beam.

The advantage of this solution consists in unlimited possibility to shift and to rectify the assembling beams on the supporting beam.

In some cases it is advantageous to attach the front leg and the rear one to the rest part of the structure by means of disassembling joint even if the joint is made as immobile. It is advantageous to use this solution if completed structures are transported very far away. The structures with disassembled legs occupy less space.

Advantageously, the support structures are used to be anchored on drilling bases if these are installed on unreinforced surfaces or to be anchored on clamps if installed at reinforced surfaces.

The diameter of tubes, forming the front leg and the rear one, is chosen so that the clamps, or the drilling bases respectively, ale placed inside or outside the front and rear leg. With the internal diameter of the drilling base, or the clamp respectively, greater than the diameter of the tube, forming front and rear legs, the front leg and the rear one are placed inside the drilling base or the clamp respectively. With the internal diameter of the tube, making the front leg and the rear one, greater than the outer diameter of the drilling base, or the clamp respectively, the front and rear leg are pulled over the top part of the drilling base or the clamp respectively. This solution is more suitable with respect to preventing the rainwater from penetrating into the drilling base or the clamp respectively.

The front and rear legs can be provided directly with a joining element in the form of a plate. The joining element is connected with the front and rear legs by welded or other joint. In such case, neither drilling base nor clamps are used.

### BRIEF DESCRIPTION OF DRAWINGS

Exemplary embodiments of the proposed solution are described with respect of following figures:

FIG. 1—The support structure with an equilateral triangle and immobile attachment with legs.

FIG. 2—The support structure with an equilateral triangle and legs joined in a sliding way.

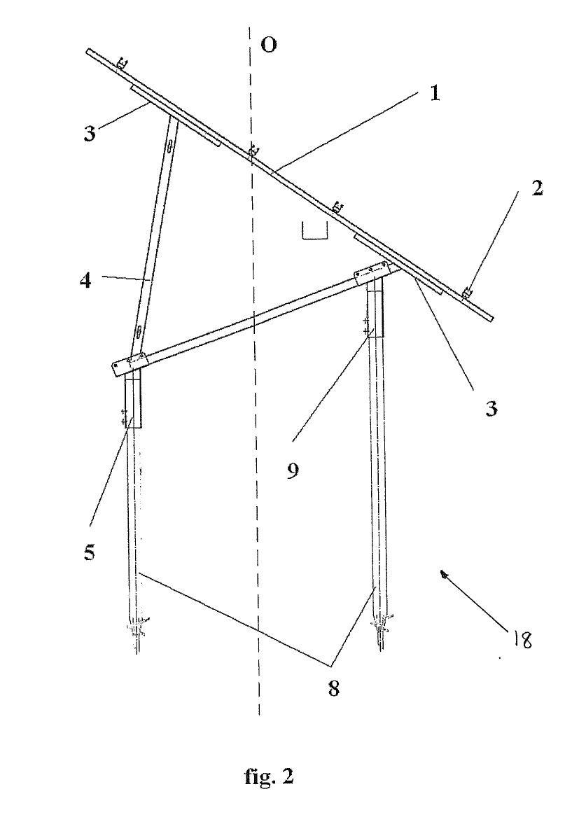

FIG. 3—The set of six support structures interconnected with longitudinal struts and ropes.

FIG. 4—The positioning realization of the support structure with an equilateral triangle in a summer setting with supporting beam inclination of 30°.

FIG. 5—The positioning realization of the support structure with an equilateral triangle in a winter setting with supporting beam inclination of 50°.

FIG. 6—The holder and a connecting element for installation of the support structure on reinforced surfaces or roofs.

FIG. 7—The front leg with accessories for sliding connection to the rest part of the structure.

FIG. 8—The support structure with a skew bottom beam and a vertical rear beam.

FIG. 9—The support structure with a skew bottom beam, a vertical rear beam, and struts.

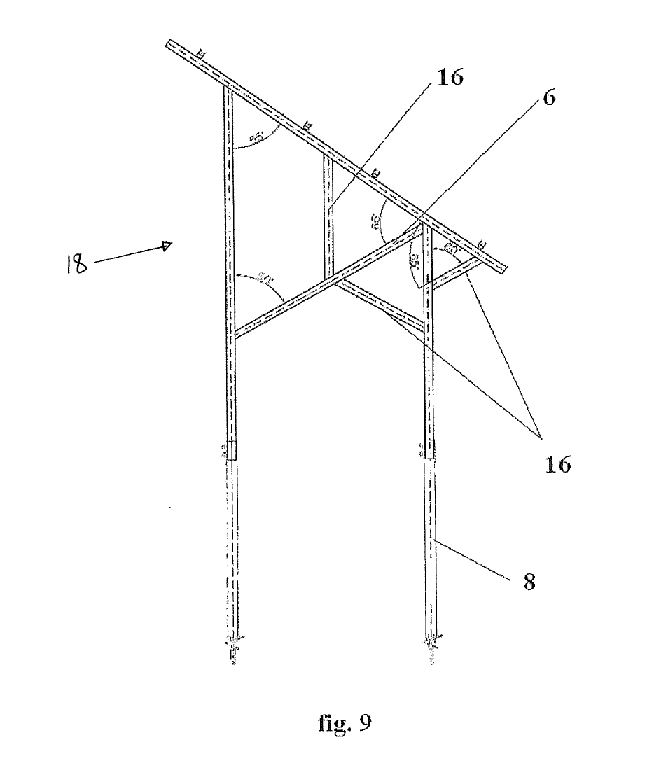

FIG. 10—The support structure with the skew bottom beam, the vertical rear beam, two struts, and the movable rear leg.

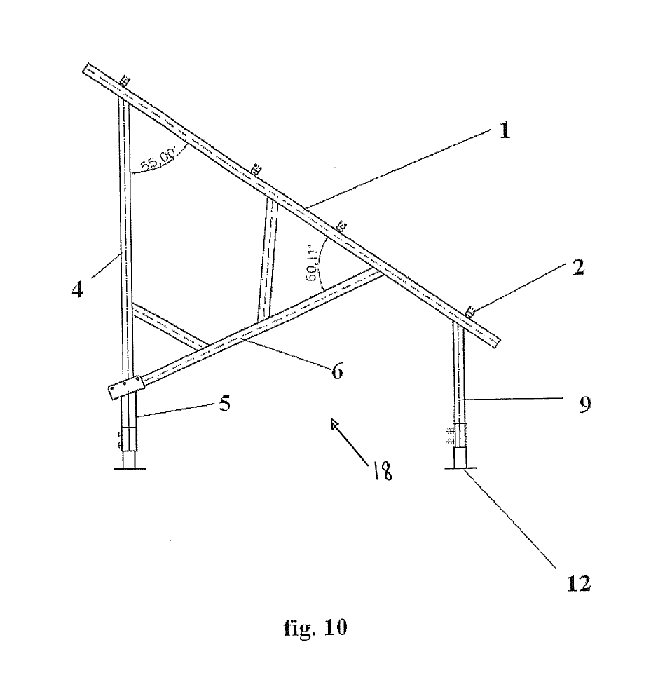

FIG. 11—The support structure with a horizontal bottom beam, the vertical rear beam, the movable rear leg, and one strut with braces.

FIG. 12—The positioning realization of the support structure with the vertical rear beam and one strut.

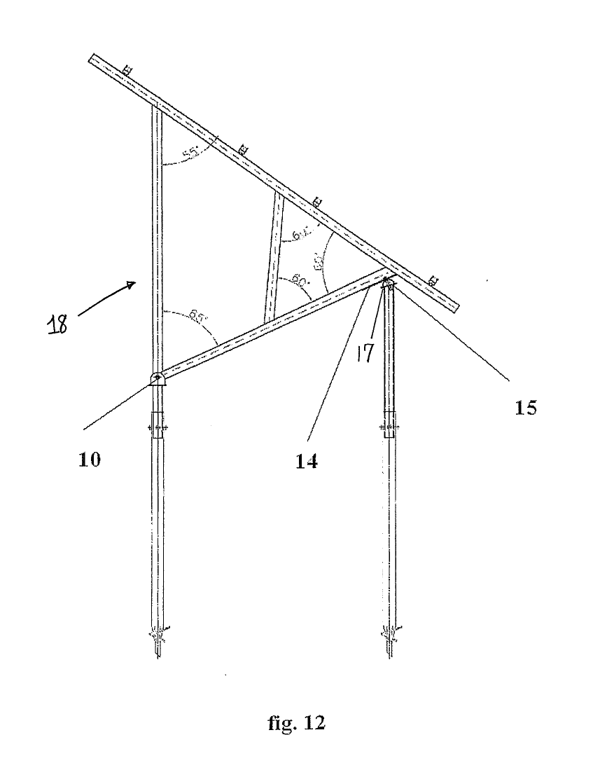

FIG. 13—The rigid support structure for high loads with one strut and three arrays of solar panels.

FIG. 14—The positioning realization of the support structure for high loads with one strut and three rows of solar panels.

### BEST MODES FOR CARRYING OUT THE INVENTION

### Example 1

The support structure of photovoltaic devices, according to the proposed technical solution, is made of aluminium and is solved as positioning one. It consists of a rear leg 5, a front leg 9, a rear beam 4, a bottom beam 6, and a supporting beam 1. In this case, the supporting beam 1 is made of a closed rectangular-section beam with dimensions of 50 mm×50 mm×3000 mm. In the supporting beam 1, circular orifices are made for placing clips 2 serving to attach longitudinal struts 7. The rear leg 5 is joined to the rest part of the structure by means of a pivot 10 with the horizontal axis of rotation which is perpendicular to the bottom beam 6 simultaneously. The front leg 9 is attached to the bottom beam 6 in a sliding way with respect to the longitudinal axis of the bottom beam 6. The sliding attachment is solved by means of a positioning plate 14 and a glider 15 with a clamping plate. The positioning plate 14 has rectangular shape and is welded to the bottom beam 6 from the bottom side with its longer axis conformal with the longitudinal axis of the bottom beam 6. In the positioning plate 14, three pairs of orifices are made with each pair serving to set the inclination of the support structure into certain position as defined beforehand. The top end of the front leg 9 is provided with the glider 15, having hemispheric shape if being viewed from the side, and with the clamping plate. In the clamping plate, there are two orifices, each on each lateral side. The actual connection of the front leg 9 to the positioning plate 14 is made with two screws passing through both orifices in the clamping plate and through one pair of orifices in the positioning plate 14.

The diameter of the internal part of a tube, forming the rear leg 5 and the front leg 9, is greater than the outer diameter of the top part of the drilling bases 8 on which the whole structure is located. Therefore, in this case the drilling bases 8 are placed inside the front leg 9 and the rear leg 5 and are made safe from sliding by means of several screws passing through the wall of the tube which forms the rear leg 5 and the front leg 9. This solution enables to change the inclination of the supporting beam 1 (and even of the photovoltaic panels too) relative to the horizontal line.

A series of several support structures, in compliance with the proposed solution, is located in an array side by side, and individual support structures are mutually interconnected with several longitudinal struts 7. The actual photoelectric panels are mounted on the longitudinal struts 7. In each series, at least two support structures are tied mutually with several ropes 11 in order to increase the resistivity of the whole series against side wind (the so called wind bracing).

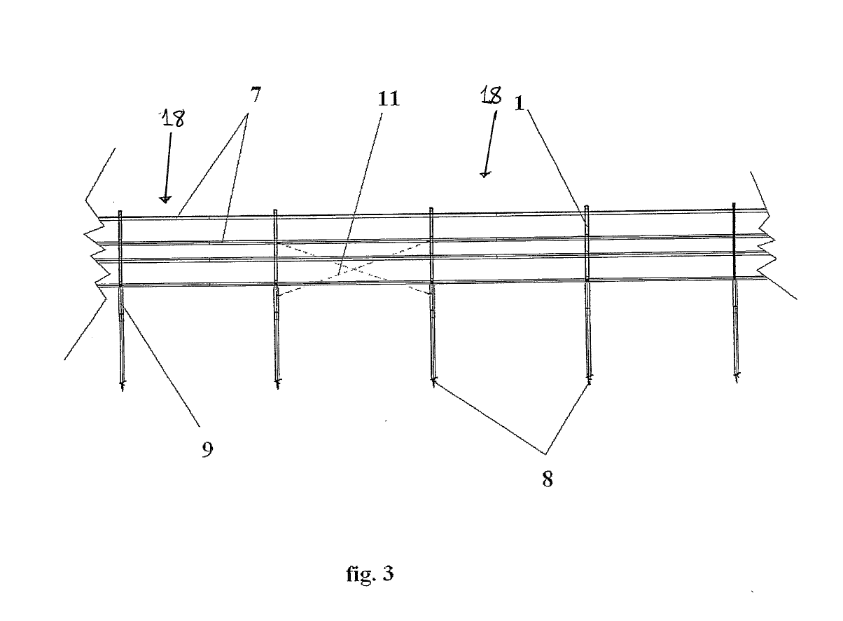

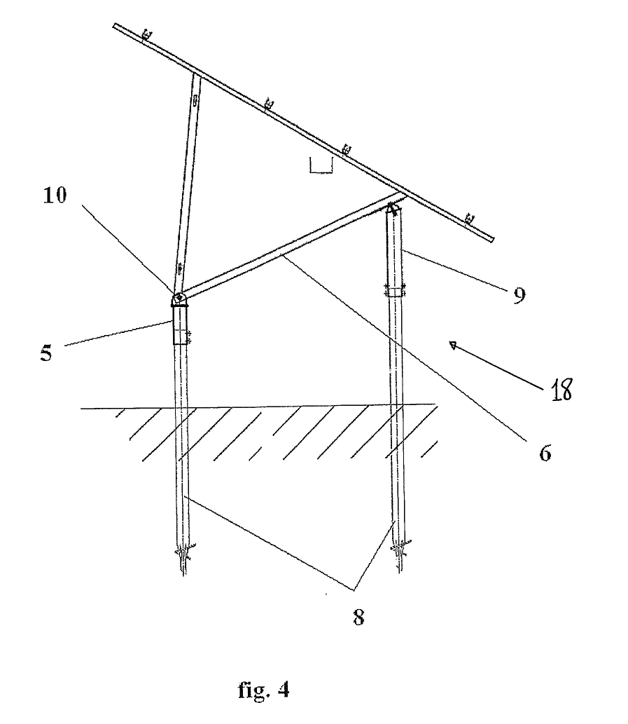

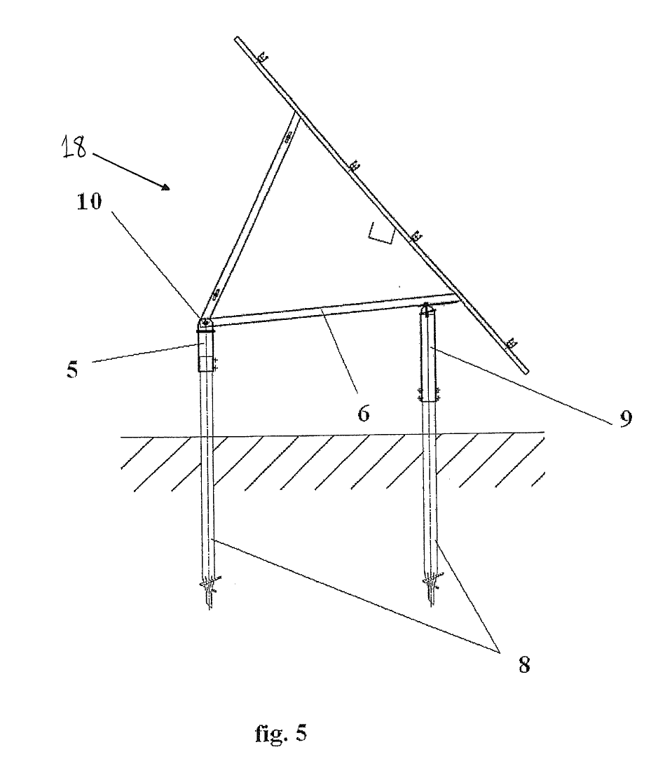

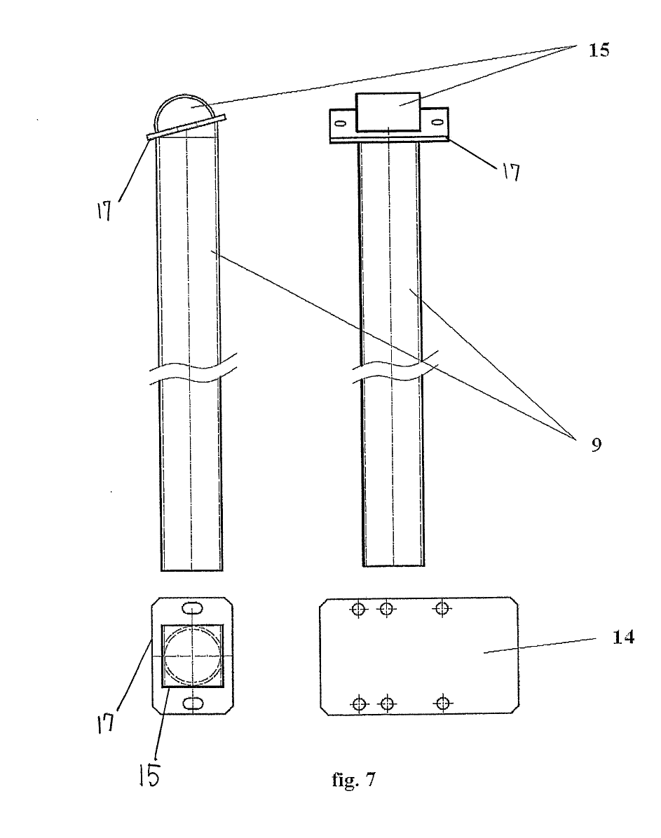

The described solution is obvious on the FIGS. 3, 4, 5, and 7.

### Example 2

The support structure of the photovoltaic devices, according to the proposed solution, is made of the zinc-coated steel and is solved as fixed one. It consists of the rear leg 5, the front leg 9, the rear beam 4, the bottom beam 6, and the supporting beam 1. In this case the supporting beam 1 is designed as the U-profile with the dimensions of 60 mm×40 mm×3000 mm. In the supporting beam 1, there are elongated orifices (grooves) for mounting the clips 2 serving to attach the longitudinal struts 7. At the connecting point with the bottom beam 6 and at the connecting point with the rear beam 4, the supporting beam 1 is always underlaid with one brace 3 which provides that the spot pressure, in the joint point, is distributed into greater length of the supporting beam 1. The rear leg 5 and the front leg 9 too are fixed rigidly to the rest part of the structure. Then, the whole structure is located on two drilling bases 8 again. Instead of the drilling bases 8, a holder 12 or a connecting element 13 can be used to fix the support structure on a roof or other rigid surface (e.g. an airport surface). Then in such case, the holders 12 are attached to the front leg 9 and the rear leg 5 by means of several screws, namely in the same way as it has been done in the case of the drilling bases 8. As a rule, the connection between the holders 12 and the roof or other rigid surface is made by means of several screws passing through the orifices in the bottom plate of the holders 12. The connecting element 13, in the form of a plate with several orifices, is attached rigidly to the front leg 9 and to the rear leg 5 by means of a welding or another joint. The coupling between the connecting element 13 and the roof or other rigid surface is made again by means of several screws passing through the orifices in the connecting element 13.

A series of several support structures, in compliance with the proposed solution, is placed in an array side by side, and individual support structures are mutually interconnected with several longitudinal struts 7. On the longitudinal struts 7, the actual photoelectric panels are mounted. In each series, at least two support structures are tied mutually with ropes 11 in order to increase the resistivity of the whole series against side wind (i.e. the so called wind bracing).

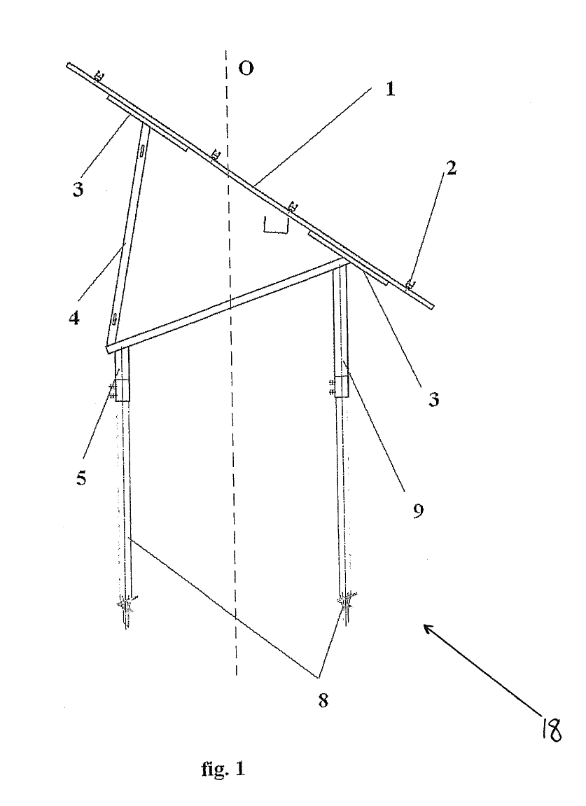

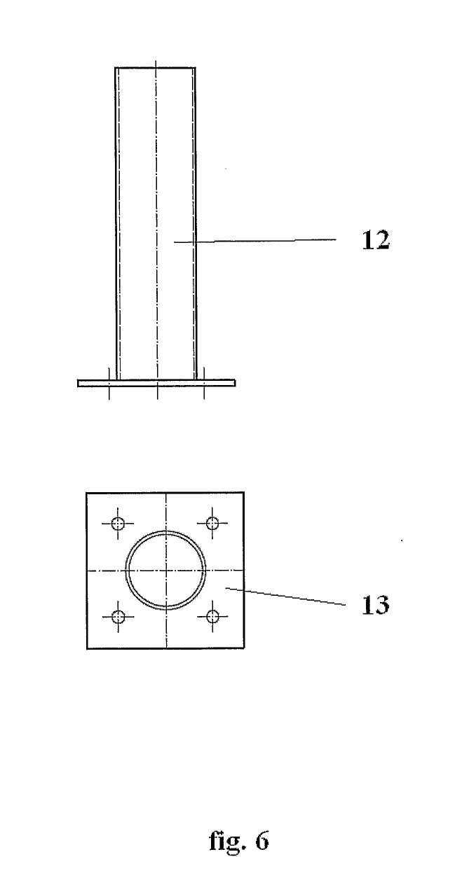

The described solution is obvious on the FIGS. 1, 3, and 6.

### Example 3

The support structure of the photovoltaic devices, according to the proposed technical solution, consists of the rear beam 4, the bottom beam 6, and the supporting beam 1. These three beams form a triangular base of the support structure, said base being completed with the rear leg 5 and the front leg 9. In the triangle the rear beam 4 is situated vertically. The bottom beam 6 is situated so that, in this case, its joint to the front leg 9 is higher than its joint to the rear beam 4. The value of each internal angle is in the range of 45° to 75°. In this case, the sizes of the internal angles are 55°, 60°, and 65°. In this case, the rear leg 5 and the front leg 9 are joined to the resting part of the structure with a rigid non-dismountable connection. On the supporting beam 1 four clips 2 are laid. To the clips 2, the longitudinal struts 7 are fastened which interconnect the individual support structures mutually. The whole support structure lies on two drilling bases 8. In this case, the internal diameter of tubes, forming the drilling bases 8, is greater than the outer diameter of the front leg 9 and the rear leg 5. Therefore the front leg 9 and the rear leg 5 are shifted into the drilling bases 8 and fixed with several screws.

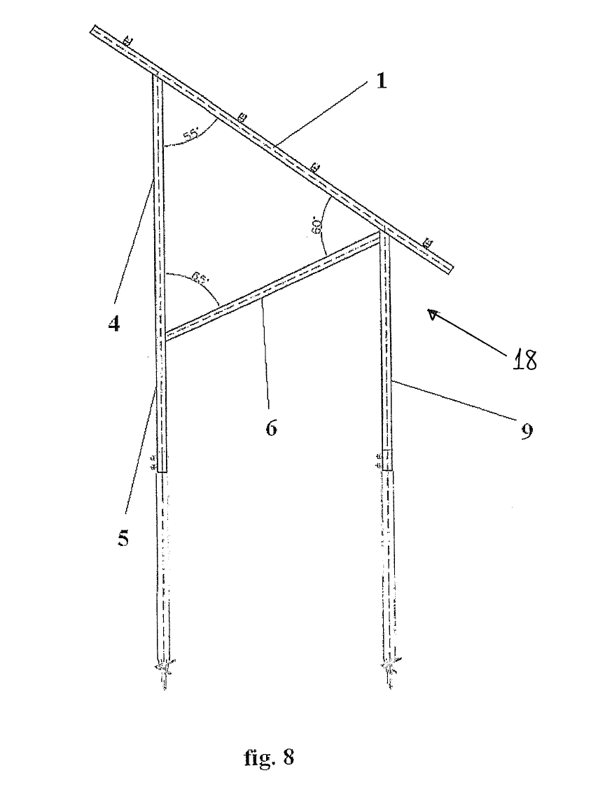

The described solution can be seen on the FIG. 8.

### Example 4

The support structure of the photovoltaic devices, according to the proposed technical solution, consists of the rear beam 4, the bottom beam 6, and the supporting beam 1. These three beams form a triangular base for the support structure, said base being completed with the rear leg 5 and the front leg 9. In the triangle the rear beam 4 is situated vertically. The bottom beam 6 is situated horizontally and is attached to the rear beam 4 at the angle of 90° therefore. To the rest of the structure, the rear leg 5 is fixed in a sliding way. One strut 16 is located inside the triangle, consisting of the supporting beam 1, the rear beam 4, and the bottom beam 6. On the supporting beam 1 four clips 2 are located. On the clips 2, the longitudinal struts 7 are fastened which interconnect mutually the structures. The whole support structure lies on two drilling bases 8. In this case, the internal diameter of the tube, forming the first drilling base 8, is greater than the diameter of the front leg 9.

In this case, the outer diameter of the second drilling base 8 is smaller than the internal diameter of the tube which forms the rear leg 5.

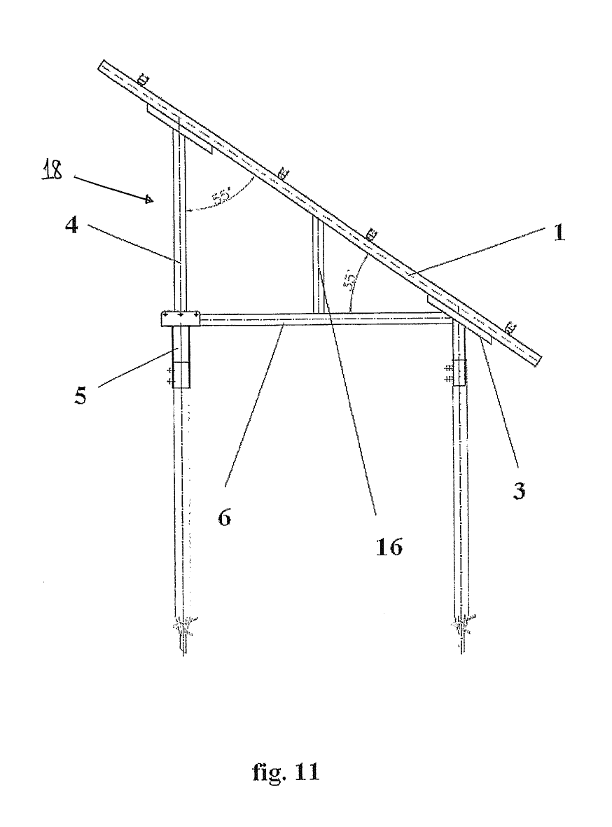

The described solution is obvious from the FIG. 11.

### Example 5

Assembled conformably to the proposed technical solution, the support structure of the photo-voltaic devices for big loads by photovoltaic panels consists of the supporting beam 1, the rear beam 4, and the bottom beam 6 which form a rectangular triangle. The triangle is situated on the front leg 9 and the rear leg 5 which are fixed on the drilling bases 8 in this case. The spacing of the legs equals 1800 mm. In this case, the supporting beam 1 is 4500 mm long and is made of two L-section beams. These L-section beams are situated upwards with their horizontal parts and mutually one to the other with vertical parts thereof. Between the vertical parts of the L-section beams an assembling gap is left to install the screws which hold the longitudinal struts 7. On the supporting beam 1, three pairs of the longitudinal struts 7 are fixed serving to attach three rows of the photovoltaic panels with dimensions of 800 mm×1580 mm. On the support structure, the photovoltaic panels are directed, with their longer sides, conformably to the supporting beam 1.

In this case, the support structure is reinforced with one strut 16 located inside the triangle which consists of one supporting beam 1, rear beam 4, and the bottom beam 6.

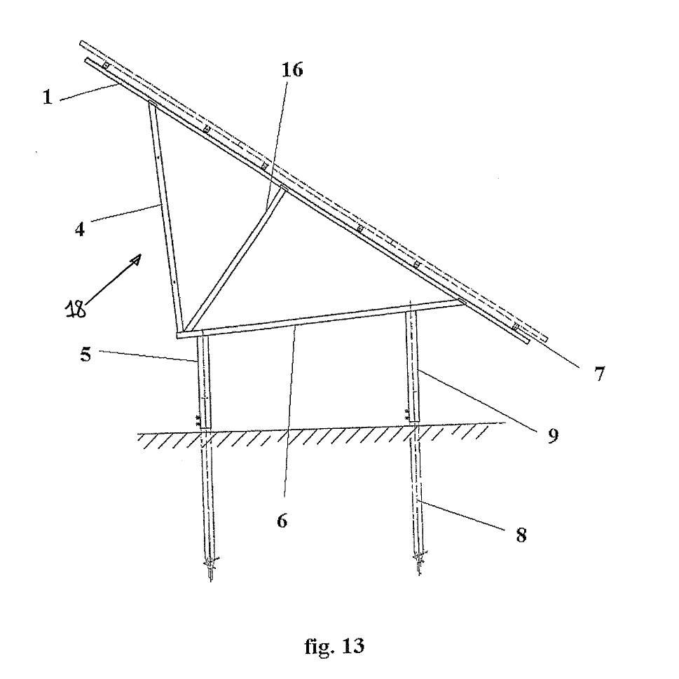

The exemplary embodiment can be seen on the FIG. 13.

### Example 6

Assembled according to the proposed technical solution, the support structure of the photovoltaic devices for big loads by photovoltaic panels differs from the solution described in the Example 5 in that the supporting beam 1 can be positioned against the horizontal line. This is reached by fastening the rear leg 5 to the structure triangle by means of a pivot with a horizontally axis of rotation which is perpendicular to the supporting beam 1. The front leg 9 is fastened to the bottom beam 6 in a sliding way. Simultaneously, the height and length of the front leg 9 can be set thanks to its clamping on the drilling base 8. Because of this solution, the inclination of the support structure with the photovoltaic panels can be changed simply and usefully with respect to diverse height of the Sun above the horizon in various seasons of the year.

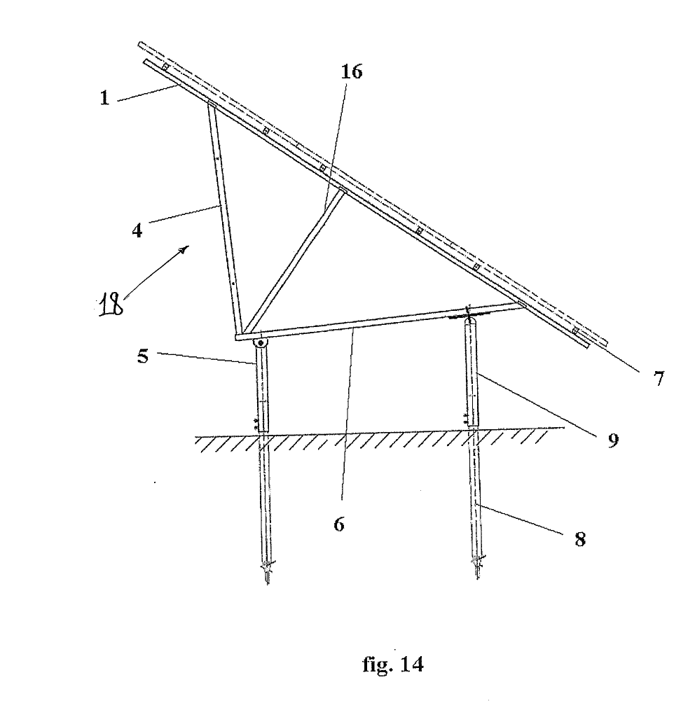

The exemplary embodiment is obvious on the FIG. 14.

### LIST OF REFERENCE SYMBOLS

1—supporting beam
2—clip
3—brace
4—rear beam
5—rear leg
6—bottom beam
7—longitudinal strut
8—drilling base
9—front leg
10—pivot
11—rope
12—holder
13—connecting element
14—positioning plate
15—glider
16—strut
O—central axis

1. Support structure of photovoltaic devices adapted to be anchored on drilling bases for installing at unreinforced surfaces adapted to be anchored on holders for installing at reinforced surfaces comprising:
a rear leg, a front leg, a rear beam, a bottom beam, and a supporting beam, wherein the internal angles triangle forward by the supporting beam, bottom beam, and the rear beam, of a equal 60° with a tolerance of ±5°,
and further wherein a distance between a top part of the rear beam and a central axis is less than a distance between a bottom part of the rear beam and the central axis, and simultaneously, wherein the bottom beam is situated so that a connection of the front leg with the bottom beam is located higher than a connection of the bottom beam with the rear leg.

2. Support structure of photovoltaic devices adapted to be anchored on drilling bases for installing at unreinforced surfaces or adapted to be anchored on holders for installing at reinforced surfaces comprising:
a rear leg, a front leg, a rear beam, a bottom beam, and a supporting beam,
wherein the rear beam is situated substantially vertically and values of each internal angle in a triangle formed by the supporting beam, bottom beam, and the rear beam, are in the range of 45° to 75° and
wherein a connection of the bottom beam to the front leg and/or the supporting beam lies higher than a connection of the bottom beam to the rear leg and/or the rear beam.

3. Support structure of photovoltaic devices adapted to be anchored on drilling bases for installing at unreinforced surfaces or adapted to be anchored on holders for installing at reinforced surfaces comprising:
a rear leg, a front leg, a rear beam, g bottom beam, and a supporting beam,
wherein a triangle formed by the bottom beam, supporting beam, and the rear beam is formed so that the rear beam is directed vertically and its connection to the bottom beam is made at an angle of between 75° and 105°.

4. Support structure of photovoltaic devices adapted for high loading with photovoltaic panels, said structure comprising:
a supporting beam, a rear beam, and a bottom beam which together form a triangle attached to a front leg and rear leg, with the front and rear legs being fixed on drilling bases in the terrain,
wherein a supporting beam is at least about 4000 mm long and
wherein a spacing between the front leg and the rear leg is greater than 1400 mm.

5. Support structure of photovoltaic devices according to claim 1, wherein the connection of at least one of the rear leg and the front leg with the bottom beam is a sliding connection.

6. Support structure of photovoltaic devices according to claim 5, wherein the sliding connection of at least one of the rear leg and the front leg with the bottom beam is made by means of a positioning plate which is rigidly fixed to the bottom beam, said positioning plate being provided with two pairs of orifices at least at its longer opposite sides, and further
wherein a convexly shaped glider is located at least at one of a top end of the front leg and a top end of the rear leg, said glider being shaped convexly and provided with a clamping plate and one pair of orifices, and
wherein the at least one of the front leg and the rear leg is connected to the positioning plate by two screws passing through respective ones of the pair of orifices in the clamping plate and through one pair of orifices in the positioning plate, and further
wherein the connection of at least one of the rear leg and the front leg with the bottom beam includes a pivot having a substantially horizontal axis of pivoting and oriented substantially perpendicular to the bottom beam.

7. (canceled)

8. Support structure of photovoltaic devices according to claim 1, wherein at least one strut is situated inside and/or outside the triangle formed by the supporting beam, rear beam, and the bottom beam.

9. Support structure of photovoltaic devices according to claim 1, wherein the supporting beam has a U-shaped profile and the supporting beam is underlaid with a brace, which brace is in contact with the rear beam,
and further wherein the supporting beam is underlaid with a brace which is in contact with the bottom beam.

10. Support structure of photovoltaic devices according to claim 4, the supporting beam includes two opened rectangular L-shaped beams, the L-shaped beams having horizontal parts and vertical parts, wherein the horizontal parts being oriented substantially upwards and the vertical parts being oriented mutually parallel to one another and wherein an assembling gap is located between the vertical parts.

11. Support structure of photovoltaic devices according to claim 1, wherein at least one of the rear leg and the front leg is connected to the bottom beam of the structure by means of a dismountable joint.

12. Support structure of photovoltaic devices according to claim 1, further including at least one drilling base, and wherein each of the front leg and rear leg are tubes, and wherein an internal diameter of both the rear leg and the front leg is greater than an outer diameter of the at least one drilling base.

13. Support structure of photovoltaic devices according to claim 1, wherein the front leg and the rear leg are tubular and have an outer diameter, and further including at least one drilling base, and wherein the at least one drilling base has an inner diameter which is greater than the outer diameter of the rear leg and of the outer diameter of the front leg.

14. Support structure of photovoltaic devices according to claim 1, further adapted to be mounted on roofs or other reinforced surfaces and including a connecting element coupled to bottom ends of the front leg and the rear leg by a weld or other joint between the front leg and the connecting element and further between the rear leg and the connecting element.

15. Support structure of photovoltaic devices according to claim 2, wherein the connection of at least one of the rear leg and the front leg with the bottom beam is a sliding connection.

16. Support structure of photovoltaic devices according to claim 15, wherein the sliding connection of at least one of the rear leg and the front leg with the bottom beam is made by means of a positioning plate which is rigidly fixed to the bottom beam, said positioning plate being provided with two pairs of orifices at least at its longer opposite sides, and further
wherein a convexly shaped glider is located at least at one of a top end of the front leg and a top end of the rear leg, said glider being shaped convexly and provided with a clamping plate and one pair of orifices, and
wherein the at least one of the front leg and the rear leg is connected to the positioning plate by two screws passing through respective ones of the pair of orifices in the clamping plate and through one pair of orifices in the positioning plate, and further
wherein the connection of at least one of the rear leg and the front leg with the bottom beam includes a pivot having a substantially horizontal axis of pivoting and oriented substantially perpendicular to the bottom beam.

17. Support structure of photovoltaic devices according to claim 3, wherein the connection of at least one of the rear leg and the front leg with the bottom beam is a sliding connection.

18. Support structure of photovoltaic devices according to claim 17, wherein the sliding connection of at least one of the rear leg and the front leg with the bottom beam is made by means of a positioning plate which is rigidly fixed to the bottom beam, said positioning plate being provided with two pairs of orifices at least at its longer opposite sides, and further
wherein a convexly shaped glider is located at least at one of a top end of the front leg and a top end of the rear leg, said glider being shaped convexly and provided with a clamping plate and one pair of orifices, and
wherein the at least one of the front leg and the rear leg is connected to the positioning plate by two screws passing through respective ones of the pair of orifices in the clamping plate and through one pair of orifices in the positioning plate, and further
wherein the connection of at least one of the rear leg and the front leg with the bottom beam includes a pivot having a substantially horizontal axis of pivoting and oriented substantially perpendicular to the bottom beam.

19. Support structure of photovoltaic devices according to claim 4, wherein the connection of at least one of the rear leg and the front leg with the bottom beam is a sliding connection.

20. Support structure of photovoltaic devices according to claim 19, wherein the sliding connection of at least one of the rear leg and the front leg with the bottom beam is made by means of a positioning plate which is rigidly fixed to the bottom beam, said positioning plate being provided with two pairs of orifices at least at its longer opposite sides, and further
wherein a convexly shaped glider is located at least at one of a top end of the front leg and a top end of the rear leg, said glider being shaped convexly and provided with a clamping plate and one pair of orifices, and
wherein the at least one of the front leg and the rear leg is connected to the positioning plate by two screws passing through respective ones of the pair of orifices in the clamping plate and through one pair of orifices in the positioning plate, and further
wherein the connection of at least one of the rear leg and the front leg with the bottom beam includes a pivot having a substantially horizontal axis of pivoting and oriented substantially perpendicular to the bottom beam.
